(19) United States
(12) Patent Application Publication
(10) Pub. No.: US 2014/0332795 A1
(43) Pub. Date: Nov. 13, 2014

(54) TRANSPARENT ANODE FOR AN OLED

(71) Applicant: SAINT-GOBAIN GLASS FRANCE, Courbevoie (FR)

(72) Inventors: Denis Guimard, Paris (FR); Julien Booz, Roissy En Brie (FR); Augustin Palacios-Laloy, Paris (FR)

(21) Appl. No.: 14/367,688

(22) PCT Filed: Dec. 27, 2012
(86) PCT No.: PCT/FR2012/053093

§ 371 Date: Jun. 20, 2014

(30) Foreign Application Priority Data
Dec. 27, 2011 (FR) 1162472
Mar. 13, 2012 (FR) 1252238

(51) Int. Cl. H01L 51/52; H01L 51/00

(52) U.S. Cl. CPC H01L 51/5215; H01L 51/0021
USPC 257/40; 428/697; 219/162

(57) ABSTRACT

A transparent electrode for an organic light-emitting diode including, on a transparent support made of mineral glass, n individual stacks of thin layers, each individual stack successively including, starting from the glass support,
(a) a layer of mixed tin zinc oxide,
(b) a crystalline layer of zinc oxide, optionally doped with aluminum,
(c) a metallic silver layer, in contact with the zinc oxide layer, and
   positioned between each silver layer and the mixed tin zinc oxide layer or layers closest thereto is (d) a layer made of silicon nitride or made of silica, optionally doped with a metal. There is also provided It also relates to an an organic light-emitting diode device containing such an electrode and to a process for manufacturing such a device.

The present invention relates to a transparent supported electrode, comprising a stack of thin layers of silver and of metal oxides, an organic light-emitting diode (OLED) optoelectronic device containing at least one such electrode, preferably as an anode, and to a process for manufacturing such a device.

Transparent conductive oxides (TCOs) and in particular ITO (indium tin oxide) are widely known and used as transparent material for forming transparent thin electrodes for electronic devices and in particular optoelectronic devices.

In the field of OLEDs (organic light-emitting diodes), ITO is used as an anode material since it is characterized by a high work function, generally between 4.5 and 5.1 eV. For large-area OLEDs, the sheet resistance (R□) of the ITO is however too high and, in order to obtain a good uniformity of light emission, it is necessary to coat the ITO layer with one or more conductive thin layers, such as silver layers.

The use of stacks of thin layers comprising one or more silver layers for increasing the conductivity of TCO-based anodes is also known. An anode for an OLED comprising both a layer of ITO and one or more silver layers is described, for example, in international application WO 2009/083693 in the name of the applicant.

In order to obtain a good crystallinity of the silver layer, the latter is, as is known, deposited on a crystalline underlayer of zinc oxide (ZnO), generally doped with aluminum (AZO). This crystalline underlayer of ZnO or of AZO is deposited, in turn, on a relatively more amorphous layer of mixed tin zinc oxide (SnZnO) which makes it possible to limit the RMS roughness of the following layers to a value generally of less than 1 nm.

Finally, each silver layer is generally covered with a thin metallic layer, referred to as a “blocker” or “overblocker”, typically of 0.5 to 5 nm, intended to protect the silver against oxidation during the step of depositing the following layer. These protective layers are also sometimes described as sacrificial layers because they are consumed by reacting with the oxygen against which they must protect the underlying silver layer.

The processes for manufacturing optoelectronic devices containing electrodes with such stacks of silver layers generally comprise at least one step of heating at high temperature (150° C.-350° C.) with a view to the etching, cleaning or passivation of the electrode.

The applicant has observed that the optical and electrical properties of the silver stacks were modified by this, often inevitable, annealing step. Annealing at a moderate temperature certainly improves the crystallinity of the silver layers and consequently the sheet resistance and the absorption of the electrode, but the applicant has observed that, unfortunately, at higher annealing temperatures, typically above 200° C., an increase in the sheet resistance and the absorption (a reduction of the light transmission) was observed.

The applicant has furthermore observed the appearance, during the annealing, of undesirable surface imperfections, referred to hereinbelow as “dendrites”. Dendrites are local depletions of silver which create, at the surface of the electrode, depressions having a depth of around 5 to 10 nm and a diameter ranging from about ten nanometers to about ten micrometers approximately. In the center of such a “well”, a protruding part is often observed.

This local increase in the roughness risks resulting in an increase in short-circuit currents.

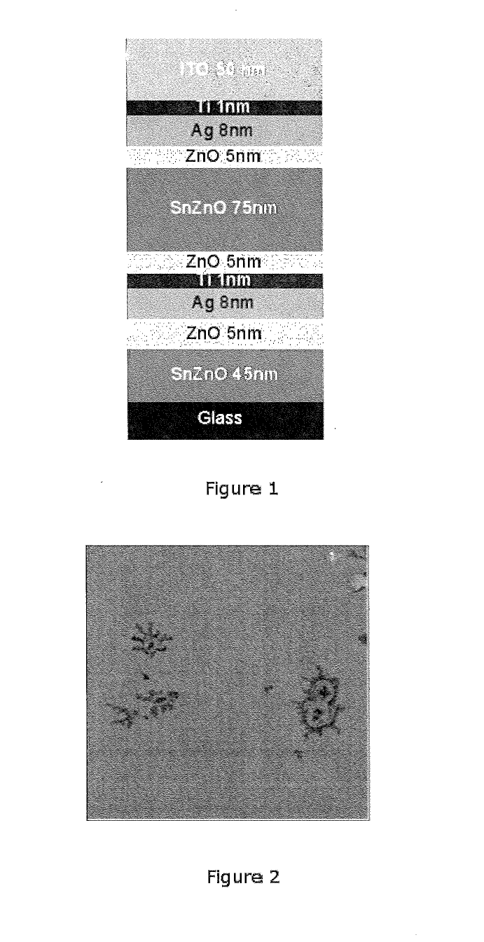

FIG. 2 is a scanning electron microscopy (SEM) image of dendrites observed after an annealing of one hour at 300° C. of a stack of thin layers, with two silver layers, according to the prior art represented in FIG. 1.

After many experiments, the purpose of which was to understand the mechanisms of formation of dendrites and to reduce, or even prevent, their appearance, it has turned out that increasing the thickness of the metallic overblocker and/or inserting an underblocker makes it possible to reduce, but not to completely eliminate, the formation of dendrites. Furthermore, such measures inevitably result in an undesirable reduction in the light transmission (LT) of the electrode.

Although the applicant, after many tests, has not completely elucidated the mechanism of formation of dendrites, it was able to establish that the problem came from the layer of SnZnO, because a stack with an underlayer of ZnO, in the absence of SnZnO, did not give dendrites. it is likely that the presence of an excess of oxygen in the SnZnO layer is the cause of these defects. Without wishing to be tied to any one theory, the applicant theorizes that oxygen present in excess in the amorphous layer of SnZnO diffuses, during the annealing, into the thickness of the electrode and, when it arrives at the silver layer, oxidizes the latter. The formation of silver oxide could result in an increase in the local stresses causing the dendrites.

The present invention is based on the idea of protecting the silver layer or layers by inserting a protective layer, which is assumed to operate as a barrier to oxygen, between the silver layer and the SnZnO layer or layers of the stack. This insertion must not of course take place between the silver layer and the directly underlying crystalline layer of ZnO (AZO) which is essential for good crystalline growth during the deposition of the silver layer.

The applicant discovered that silicon nitride (Si₃N₄) and silica (SiO₂), even at a small thickness, made it possible to play this protective role and to effectively reduce, or even eliminate, the formation of dendrites without their presence resulting in a degradation of the electrical and optical properties of the electrode before and after annealing. As will be shown below in the example, it was also observed that the presence of Si₃N₄ or SiO₂ resulted in an advantageous decrease in the sheet resistance and in the absorption.

It is important to also note that the presence of the silicon nitride or silica layer between the silver layer and the SnZnO layer has no significant impact on the RMS roughness (measured by AFM on 5 μm×5 μm) of the sample, which increases by at most around 0.2 nm.

One subject of the present invention is consequently a transparent electrode for an organic light-emitting diode (OLED), comprising, on a transparent support made of mineral glass, n individual stacks of thin layers, each individual stack successively comprising, starting from the glass support,
(a) a layer of mixed tin zinc oxide (referred to as SnZnO, more specifically SnₓZn_{y}O), preferably having a thickness of at least 15 nm and even of at least 25 nm, which is optionally doped,
(b) a crystalline layer of zinc oxide (referred to as ZnO), optionally doped preferably with aluminum (referred to as AZO) and/or with gallium (referred to as GZO, AGZO), preferably having a thickness of less than 15 nm, better still of less than or equal to 10 nm, and preferably of at least 3 nm, and
(c) a metallic silver layer, in contact with the ZnO (zinc oxide) layer,
   the electrode being characterized in that positioned between each silver layer and the SnZnO layer or layers closest thereto is (d) a layer made of silicon nitride (referred to as Si₃N₄) or made of silica (referred to as SiO₂), optionally doped with a metal.

The layer (a) is preferably an essentially amorphous layer of SnZnO. The ratio of the number of Sn atoms to the number of Zn atoms is preferably between 20/80 and 80/20, in particular between 30/70 and 70/30. Preferably, the percentage, by total weight of metal, of Sn preferably ranges from 20% to 90% (and preferably from 80% to 10% for Zn) and in particular from 30% to 80% (and preferably from 70% to 20% for Zn), in particular the Sn/(Sn+Zn) weight ratio preferably ranges from 20% to 90% and in particular from 30% to 80%. And/or it is preferred that the sum of the weight percentages of Sn+Zn is at least 90%, by total weight of metal, better still at least 95% preferably and even at least 97%. It is also preferred that it is devoid of indium or at least has an indium percentage, by total weight of metal, of less than 10% or even less than 5%. It is preferred that the layer (a) essentially consists of tin zinc oxide.

In order to do this, it is preferred to use a metal target made of zinc and of tin, for which the percentage by weight (total weight of the target) of Sn preferably ranges from 20% to 90% (and preferably from 80% to 10% for Zn) and in particular from 30% to 80% for Sn (and preferably from 80% to 30% for Zn), in particular the Sn/(Sn+Zn) ratio preferably ranges from 20% to 90% and in particular from 30% to 80% and/or the sum of the weight percentages of Sn+Zn is at least 90%, better still preferably at least 90% and even at least 95%, or even at least 97%. The metal target made of zinc and tin may be doped with a metal, preferably with antimony (Sb).

As indicated above, the role of the layer a) is to smooth, that is to say to limit the roughness of, the thin layers (AZO and Ag, or GZO and preferably Ag) deposited subsequently. It may be doped with a metal, for example with antimony (Sb).

In the present application, when mention is made of a “succession of layers”, “successive layers”, or else a layer located on top of or underneath another layer, reference is always made to the process for manufacturing the electrode during which the layers are deposited one after the other on the transparent substrate. The first layer is therefore that which is the closest to the substrate, all the “following” layers being those located “on top of” this first layer and “underneath” the layers deposited afterwards.

The expression “electrode for an OLED” used in the present application implies, inter alia, that the present invention does not encompass similar multilayer structures for which the last layer (the outermost layer) is a non-conductive layer, such as a layer made of silicon carbide, or preferably at the very least a non-conductive layer that is thick enough to prevent the vertical conduction from silver to the layer containing a light-emitting organic substance. Indeed, such structures would be unsuitable for use as an electrode.

In the present invention the SnZnO layer is either designated (a) or a), the ZnO layer is either designated (b) or b), the Ag layer is either designated (c) or c) and the Si₃N₄ or SiO₂ layer is either designated (d) or d).

The electrode of the present invention preferably comprises from 1 to 4 individual stacks with a silver layer, that is to say n is preferably an integer between 1 and 4, in particular between 2 and 3, and is in particular equal to 2.

Naturally, according to the invention, the expression between a limit A and a limit B includes the limits A and B.

These silver layers preferably have a thickness between 4 nm and 30 nm, in particular between 5 and 25 nm and particularly preferably between 6 and 12 nm.

Preferably, the total thickness of the electrode is less than 300 nm, and even less than 250 nm.

Preferably, a thin layer is a layer having a thickness of less than 150 nm.

The protective layer is preferably a layer of Si₃N₄ or of SiO₂ that is “doped”, for example with aluminum or zirconium. As is known, silicon nitride is deposited by reactive sputtering from a metallic (Si) target with use of nitrogen as reactive gas.

And, as is known, silica is deposited by reactive sputtering from a metal (Si) target with use of oxygen as reactive gas. Aluminum and/or zirconium are present in the target (Si) in relatively large amounts, generally ranging from a few percent (at least 1%) to more than 10%, typically up to 20%, ranging beyond a conventional doping, and intended to give the target a sufficient conductivity.

In the present invention, a layer of silicon nitride doped with aluminum (especially the dendrite barrier layer) preferably comprises a weight percentage of aluminum to the weight percentage of silicon and aluminum, therefore Al/(Si+Al), ranging from 5% to 15%. The aluminum-doped silicon nitride corresponds more precisely to a silicon nitride comprising aluminum (SiAlN).

In the present invention, preferably, in a layer of silicon nitride doped with aluminum or even zirconium (especially the dendrite barrier layer) the sum of the weight percentages of Si+Al or Si+Zr+Al is at least 90% by total weight of metal, or preferably 95% by weight or even at least 99%.

In the present invention, a layer of silicon nitride doped with aluminum and with zirconium corresponds more precisely to a silicon zirconium nitride comprising aluminum. The weight percentage of zirconium in the layer may be from 10% to 25% by total weight of metal.

In the present invention, the aluminum-doped silicon oxide layer (dendrite barrier) preferably comprises a weight percentage of aluminum to the weight percentage of silicon and aluminum, therefore Al/(Si+Al), ranging from 5% to 15%. The aluminum-doped silicon oxide corresponds more precisely to a silicon oxide comprising aluminum.

Preferably, in the layer of silica doped with aluminum or even with zirconium (dendrite barrier layer) the sum of the weight percentages of Si+Al or Si+Zr+Al is at least 90% by total weight of metal, or preferably at least 95% or even at least 99%.

As already mentioned in the introduction, the silica and the silicon nitride have proved to be effective protective layers, even at a small thickness. The thickness necessary for reducing or preventing the formation of dendrites increases with the annealing temperature and time. For annealing temperatures below 450° C. and annealing times of less than 1 h, thicknesses of the layers of less than 15 nm appear to be sufficient.

The thickness of the layer of Si₃N₄ or of SiO₂ (especially in each individual stack, and between each individual stack) is preferably between 1 and 10 nm, in particular between 2 and 9 nm, and particularly preferably between 3 and 8 nm.

Each silver layer of an individual stack according to the invention is protected by the layer of Si₃N₄ or SiO₂ not only from the SnZnO layer located underneath, but also from the SnZnO layer of the optional next individual stack by a layer of Si₃N₄ or SiO₂.

Preferably, each silver layer of the electrode according to the invention is protected by a layer of Si₃N₄ or SiO₂ that is especially between 1 and 10 nm in thickness, preferably between 2 and 9 nm in thickness and in particular between 3 and 8 nm in thickness, from an SnZnO layer located underneath, which layer of Si₃N₄ or SiO₂ optionally makes contact with the silver layer, and also from an SnZnO layer located above by a layer of Si₃N₄ or SiO₂ that is especially between 1 and 10 nm in thickness, preferably between 2 and 9 nm in thickness and in particular between 3 and 8 nm in thickness.

At least one of the stacks of layers, preferably each stack, also comprises, on top of the metallic silver layer, generally in contact therewith, a sacrificial layer comprising a metal chosen from titanium, nickel, chromium, niobium or a mixture thereof. As explained in the introduction, the use of such layers, better known under the name of blockers or overblockers, is known and serves mainly to protect the silver layer against a possible chemical or thermal degradation during the process for manufacturing the electrode. These layers may be partially oxidized. They are preferably very thin (generally less than 3 nm, for example of the order of 1 nm) so as not to adversely affect the light transmission of the stack.

Titanium (Ti, TiOₓ), which protects the silver layer(s) during the steps of processes for manufacturing the OLED and absorbs little, especially after heat treatment, is very particularly preferred.

The electrode may comprise at least two (preferably two) metallic silver layers, and, only on top of the last metallic silver layer, preferably in contact with the latter, is arranged a sacrificial layer comprising a metal chosen from titanium, nickel, chromium, niobium or a mixture of said metals.

For an electrode which is a silver bilayer, it turns out that a single overblocker, preferably made of titanium, on the second silver layer may sometimes be sufficient to protect the silver layers during the steps of processes for manufacturing the OLED.

For example, the electrode comprises the following (preferably strict) sequence, for n=2 or more, starting from the glass support:
SnZnO/SiO₂ or Si₃N₄/ZnO/Ag/sacrificial layer/SiO₂ or Si₃N₄/SnZnO/SiO₂ or Si₃N₄/ZnO/Ag/sacrificial layer.

Preferably, each individual stack comprises only one layer of SnZnO.

Preferably, for n equal to 2 or more, between two silver layers, there are only two layers of SiO₂ or Si₃N₄.

The ZnO layer (under the silver layer) may preferably be made of doped zinc oxide, preferably doped with Al (AZO), Ga (GZO) as indicated above, or even with B, Sc, or Sb, or else with Y, F, V, Si, Ge, Ti, Zr, Hf and even with In in order to facilitate the deposition and a lower electrical resistivity.

It is also possible to choose a crystalline layer predominantly made of zinc and containing a very small amount of tin which may be likened to a doping, referred to as ZnₐSn_{b}O, preferably with the following weight ratio Zn/(Zn+Sn)>90%, better still ≧95%. In particular, such a layer having a thickness of less than 10 nm is preferred.

As already indicated, these crystalline layers are preferred to amorphous layers for a better crystallization of the silver.

It is optionally possible to use a silicon nitride layer under a silver layer, optionally forming a layer protecting from the underlying SnZnO, in particular (at least) under the first silver layer. This Si₃N₄ layer is preferably between 1 and 15 nm in thickness, in particular between 2 and 9 nm in thickness, and in a particularly preferred way between 3 and 8 nm in thickness. Its thickness may also be dependent on optical criteria. It may be thicker than in the case of an individual stack according to the invention.

When the electrode according to the invention is used as an anode of an OLED, the outermost layer, that is to say the one in contact with the hole-transport layer (HTL), must preferably have a certain work function. Certain transparent conductive oxides are known for their relatively high work function. ITO, for example, has a work function which is generally greater than 4.5 eV, sometimes greater than 5 eV.

The electrode according to the invention consequently comprises on top of the last silver layer (especially of the n^{th} stack)—which is generally a silver layer or a blocker layer—a layer of a transparent conductive oxide (TCO), preferably a layer of ITO (tin-doped indium oxide).

This layer, described as a work function matching layer, may also be the second-to-last layer of the electrode (the anode), the last layer then being a relatively thin layer so as not to interfere with the work function matching role of the second-to-last layer and so as to preserve the vertical conductivity from the silver to the layer containing a light-emitting organic substance.

This TCO layer preferably has a thickness between 5 and 100 nm, in particular between 10 and 80 nm and particularly preferably between 10 and 50 nm.

This TCO layer is preferably directly on the (sole) overblocker of the last silver layer—the overblocker preferably being made of titanium.

Therefore, in one preferred embodiment, this TCO layer is at least one of the following metal oxides, optionally doped: indium oxide, optionally sub-stoichiometric zinc oxide, molybdenum oxide (MoO₃), tungsten oxide (WO₃), vanadium oxide (V₂O₅), indium tin oxide (ITO), indium zinc oxide (IZO or even IAZO or IGZO).

However, as ITO layer, MoO₃, WO₃ and V₂O₅ are preferred as the last, and even sole, layer on top of the overblocker.

A range of preferred proportions for the ITO is from 85% to 92% by weight of In₂O₃ and from 8% to 15% by weight of SnO₂. Preferably, it comprises no other metal oxide or less than 10% by weight of oxide out of the total weight.

As explained in the introduction, for obvious reasons the protective layer (d), located between the silver layer and the nearby SnZnO layer or layers, must not be inserted between the silver layer (c) and the underlying ZnO crystalline support layer (b).

It is therefore preferably inserted between the amorphous SnZnO layer (a) and the crystalline ZnO layer (b).

In a first advantageous embodiment, the layer positioned between each silver layer and each of the SnZnO layers closest to the silver layer is a layer of silica (SiO₂).

Each individual stack is therefore composed of, or consists of, the (preferably strict) sequence of the following layers:
(a) SnZnO/(d) Si₃N₄/(b) ZnO/(c) Ag,
   or, preferably,
(a) SnZnO/(d) Si₃N₄/(b) ZnO/(c) Ag/(e) Ti
   where the Ti layer (e) is a (sacrificial) layer of “blocker” type preferably made of titanium that is optionally partially oxidized.

Moreover, in the case of at least 2 individual stacks, it is recalled that an Si₃N₄ layer is also under each SnZnO arranged between two silver layers, preferably directly below the SnZnO. This Si₃N₄ layer is preferably between 1 and 10 nm in thickness, in particular between 2 and 9 nm in thickness, and in a particularly preferred way between 3 and 8 nm in thickness.

Thus, in this first embodiment, a layer of Si₃N₄ is chosen for all the protective layers.

In a second advantageous embodiment, the layer between each silver layer and each of the SnZnO layers closest to said silver layer is a layer of silica (SiO₂).

Each individual stack is composed of, or consists of, the (preferably strict) sequence of the following layers:
(a) SnZnO/(d) SiO₂/(b) ZnO/(c) Ag,
   or, preferably,
(a) SnZnO/(d) SiO₂/(b) ZnO/(c) Ag/(e) Ti
   where the Ti layer (e) is a layer of “blocker” type, preferably made of titanium.

Moreover, in the case of at least 2 individual stacks, it is recalled that a layer of SiO₂ is also under each SnZnO arranged between two silver layers, preferably directly below the SnZnO. This SiO₂ layer is preferably between 1 and 10 nm in thickness, in particular between 2 and 9 nm in thickness, and in a particularly preferred way between 3 and 8 nm in thickness.

Thus, in this second embodiment, a layer of SiO₂ is chosen for all the protective layers.

Furthermore, naturally, two individual stacks (one after the other) may be separated only by the SiO₂ or Si₃N₄ layer. This SiO₂ or Si₃N₄ layer is preferably between 1 and 10 nm in thickness, in particular between 2 and 9 nm in thickness, and in a particularly preferred way between 3 and 8 nm in thickness. Therefore, for example, the electrode comprises the following (preferably strict) sequence for n=2 (or more) starting from the glass support:
SnZnO/SiO₂ or Si₃N₄/ZnO/Ag/SiO₂ or Si₃N₄/SnZnO/SiO₂ or Si₃N₄/ZnO/Ag
   or
SnZnO/SiO₂ or Si₃N₄/ZnO/Ag/SiO₂ or Si₃N₄/SnZnO/SiO₂ or Si₃N₄/ZnO/Ag/sacrificial layer preferably of Ti.

In one preferred embodiment of an electrode with two metallic silver layers, comprising in this order a first silver layer, a SiO₂ or Si₃N₄ layer (preferably as the layer d)) and the individual stack comprising the layers a)/d)/b)/c), c) which corresponds to the second and preferably last metallic silver layer, at least 60%, preferably at least 80%, of the thickness of the layers separating the two silver layers is formed from the thickness of the layer a) and/or its thickness is preferably greater than or equal to 50 nm, and better still greater than or equal to 60 nm and preferably less than or equal to 100 nm.

Naturally, for n equal to 2 or more, two individual stacks (for which the last layer is preferably a metallic silver layer or a sacrificial layer, of overblocker type) may be separated by the SiO₂ or Si₃N₄ layer and by one or more other layers, and preferably by a single layer other than the SiO₂ or Si₃N₄ layer, for example ZnO or AZO or GZO.

In one embodiment, a crystalline layer of ZnO (or AZO or GZO) separates the last layer of one stack (which is preferably a metallic silver layer or a sacrificial layer, of overblocker type) from the first layer of the following stack. The (first) protective layer SiO₂ or Si₃N₄ (as the layer d) preferably) is then inserted between this layer of ZnO (or AZO or GZO) and the SnZnO layer (layer (a)) of the following individual stack.

This ZnO layer on the silver layer may preferably be made of doped zinc oxide, preferably doped with Al (AZO), Ga (GZO) or with B, Sc, or Sb, or else with Y, F, V, Si, Ge, Ti, Zr, Hf or even with In in order to make deposition easier and obtain a lower electrical resistivity. Preferably, its thickness is smaller than 30 nm, better still smaller than 15 nm and even better still smaller than or equal to 10 nm.

Consequently, in one preferred embodiment of the electrode of the present invention, each protective layer of SiO₂ or Si₃N₄ is in contact, on one side, with a layer of ZnO, preferably doped with aluminum, and on the other side with a layer of SnZnO.

It results from the foregoing that, when n is at least equal to 2, that is to say when the electrode of the present invention comprises at least two individual stacks of thin layers as described above, it preferably comprises between the last layer of one stack (which is preferably a metallic silver layer or a sacrificial layer, of overblocker type) and the first layer of the following stack, successively:
a layer of ZnO, preferably doped with aluminum, preferably smaller than 20 nm and even than 10 nm in thickness; and
a layer of SiO₂ or Si₃N₄ (in addition to the layer d) and preferably analogous to the layer d)), preferably having a thickness between 1 and 10 nm, preferably between 2 and 9 nm and in particular between 3 and 8 nm, preferably making contact with the ZnO layer.

Therefore, the electrode comprises the following (preferably strict) sequence for n=2 or more, starting from the glass support:
SnZnO/SiO₂ or Si₃N₄/ZnO/Ag/ZnO/SiO₂ or Si₃N₄/SnZnO/SiO₂ or Si₃N₄/ZnO/Ag
   or else
SnZnO/SiO₂ or Si₃N₄/ZnO/Ag/sacrificial layer preferably of Ti/ZnO/SiO₂ or
Si₃N₄/SnZnO/SiO₂ or Si₃N₄/ZnO/Ag/sacrificial layer preferably of Ti/
   or even, for n=2:
SnZnO/SiO₂ or Si₃N₄/ZnO/Ag/ZnO/SiO₂ or Si₃N₄/SnZnO/SiO₂ or Si₃N₄/ZnO/Ag/sacrificial layer preferably of Ti/

The metallic silver layer may be pure, alloyed or doped, for example with Pd, Cu, Sb, etc.

For n equal to 2, preferably the electrode comprises, starting from the glass, the following (preferably strict) sequence: (p layer(s))/a)/d)/b)/c)/(q layer(s))/SiO₂ or Si₃N₄ layer/a)/d)/b)/c)/ and preferably p is an integer preferably less than or equal to 2, better still equal to 1 or even equal to 0 and q is an integer less than 3.

The added layer or layers preferably:
have an (average) optical index at 550 nm greater than or equal to 1.7, or even 1.8
and/or are made of metal oxide or of metal nitride such as silicon nitride
and/or are preferably devoid of indium
and/or are preferably amorphous
and/or have a thickness of less than 50 nm.

As a layer, in particular for the thin layer closest to the glass (referred to as the base layer), it is possible to use oxides such as niobium oxide (such as Nb₂O₅), zirconium oxide (such as ZrO₂), alumina (such as Al₂O₃), tantalum oxide (such as Ta₂O₅), tin oxide (such as SnO₂), or silicon nitride (such as Si₃N₄).

For the layers (b), the thickness is preferably less than 10 nm.

For the first layer (a) starting from the glass, the thickness is preferably greater than 20 nm, preferably from 30 to 50 nm. For the second layer (a) starting from the glass, the thickness is preferably greater than 40 nm, preferably from 60 to 100 nm, or even from 60 to 90 nm.

More broadly, in order to optimize the optical performance of an electrode according to the invention which is a silver bilayer (therefore with two silver layers), it may be advantageous to adjust the thicknesses of the layers under the first silver and between the two silver layers. By considering the optical thickness L1 of all of the layers under the first silver layer it is possible to choose L1 greater than 20 nm, better still greater than or equal to 40 nm, and less than 180 nm and even better still ranging from 100 nm to 120 nm.

By considering the optical thickness L2 of all of the layers between the first silver layer and the second silver layer, it is possible to choose L2 greater than 80 nm, better still greater than or equal to 100 nm and less than 280 nm and even better still ranging from 140 nm to 240 nm and even 140 to 220 nm.

The judicious choice of the optical thicknesses L1 and L2 makes it possible firstly to adjust the optical cavity in order to optimize the efficiency of the OLED and also to significantly reduce the colorimetric variation as a function of the angle of observation.

For the SnZnO layer between the two silver layers of a silver bilayer, the thickness is therefore preferably greater than 40 nm, preferably from 60 to 100 nm, or even 60 to 90 nm.

For n=2, a few examples of particularly preferred stacks are given below (with optional doping not specified again for the layers other than the layers under silver):
SnZnO/SiO₂ or Si₃N₄/ZnO (doped)/Ag/(Ti/)(AZO/)SiO₂ or Si₃N₄/SnZnO/SiO₂
   or
Si₃N₄/ZnO (doped)/Ag/sacrificial layer preferably of Ti/layer preferably ITO, MoO₃, WO₃, V₂O₅, or even AZO, optionally surmounted by a layer (TiN, etc.) of at most 5 nm, better still of at most 3 nm or 2 nm
   or
SnZnO/SiO₂ or Si₃N₄/AZO/Ag/(Ti)(/GZO/)SiO₂ or Si₃N₄/SnZnO/SiO₂ or Si₃N₄/AZO/Ag/sacrificial layer preferably of Ti/overlayer preferably ITO, MoO₃, WO₃, V₂O₅, or even AZO, optionally surmounted by a layer (TiN, etc.) of at most 5 nm, better still of at most 3 nm or 2 nm,
   or
SnZnO/SiO₂ or Si₃N₄/GZO/Ag/(Ti)(/GZO/)SiO₂ or Si₃N₄/SnZnO/SiO₂ or Si₃N₄/GZO/Ag/sacrificial layer preferably of Ti/layer preferably ITO, MoO₃, WO₃, V₂O₅, or even AZO, optionally surmounted by a layer (TiN, etc.) of at most 5 nm, better still of at most 3 nm or 2 nm.

And more preferably still:
SnZnO/SiO₂ or Si₃N₄/AZO/Ag/(Ti/) SiO₂ or Si₃N₄/SnZnO/SiO₂ or Si₃N₄/AZO/Ag/sacrificial layer preferably of Ti/layer preferably ITO, MoO₃, WO₃, V₂O₅, or even AZO, optionally surmounted by a layer (TiN, etc.) of at most 5 nm, better still of at most 3 nm or 2 nm
   or
SnZnO/SiO₂ or Si₃N₄/GZO/Ag/(Ti/) SiO₂ or Si₃N₄/SnZnO/SiO₂ or Si₃N₄/GZO/Ag/sacrificial layer preferably of Ti/layer preferably ITO, MoO₃, WO₃, V₂O₅, or even AZO, optionally surmounted by a layer (TiN, etc.) of at most 5 nm, better still of at most 3 nm or 2 nm.

It is understood that after annealing and/or depositing the overlying oxide layer each overblocker (titanium or NiCr, etc.) may be at least partially oxidized.

The electrode according to the invention may (preferably) form a silver bilayer or trilayer, therefore comprising at least two metallic silver layers, and, for example, n is equal to 1 and the individual stack comprises a SiO₂ or Si₃N₄ protective layer/a)/d)/b)/c) which is located on top (preferably directly or on a sacrificial overblocker layer or even on a layer of ZnO) of a silver layer, which is the first silver layer starting from the glass support, and preferably arranged under the first silver layer is a multilayer chosen from the following:
a multilayer (preferably a bilayer) which comprises a layer of SnZnO (of composition as already described for b)), preferably of at least 20 nm, followed by a layer of silicon nitride Si₃N₄ (as already described for d)) directly under the first silver layer, in particular a multilayer having thicknesses adjusted for optical properties,
a multilayer (preferably a bilayer) which comprises a layer of silicon nitride Si₃N₄ (of composition as already described for d)), for example of at least 20 nm or even of at least 35 nm or 40 nm, followed by a layer of ZnO (doped), (as already described for b)), in particular a multilayer having thicknesses adjusted for optical properties,
a multilayer (preferably a trilayer), which preferably comprises, in this order:
   a first oxide layer, preferably TiO₂ (of 20 to 50 nm preferably) or niobium oxide (such as Nb₂O₅ of 20 to 50 nm preferably), or even the oxide layers already aforementioned for instance zirconium oxide (such as ZrO₂), alumina (such as Al₂O₃), tantalum oxide (such as Ta₂O₅), tin oxide (such as SnO₂),
   a (thin) layer of silicon nitride or silica, which is also capable of forming a barrier to dendrites, such as that already described for (d) for the individual stack, preferably having a thickness between 1 and 10 nm, preferably between 2 and 9 nm and in particular between 3 and 8 nm,
   a layer of ZnO such as that already described for b) (AZO, GZO, etc.) having a thickness preferably of less than 10 nm.

The first added layer or layers preferably:
have an (average) optical index at 550 nm of greater than or equal to 1.7, even 1.8
and/or are preferably devoid of indium
and/or have thicknesses of less than 50 nm.
and/or are preferably amorphous.

For n=1, a few examples of particularly preferred stacks are given below (with optional doping not specified again for the layers other than the layers under silver):
Si₃N₄/AZO or GZO/Ag/(Ti/(AZO or GZO/) SiO₂ or Si₃N₄/SnZnO/SiO₂ or Si₃N₄/AZO or GZO/Ag/sacrificial layer preferably of Ti/layer preferably ITO, MoO₃, WO₃, V₂O₅, or even AZO, optionally surmounted by a layer (TiN, etc.) of at most 5 nm, better still of at most 3 nm or 2 nm
   or
SnZnO (of at least 20 nm, better still of at least 30 nm)/Si₃N₄/Ag/(Ti/(AZO or GZO/) SiO₂ or Si₃N₄/SnZnO/SiO₂ or Si₃N₄/AZO or GZO/Ag/sacrificial layer preferably of Ti/layer preferably ITO, MoO₃, WO₃, V₂O₅, or even AZO, optionally surmounted by a layer (TiN, etc.) of at most 5 nm, better still of at most 3 nm or 2 nm
   or
oxide layer preferably TiO₂/SiO₂ or Si₃N₄/AZO or GZO/Ag/(Ti/AZO or GZO/)SiO₂ or Si₃N₄/SnZnO/SiO₂ or Si₃N₄/ZnO (doped)/Ag/sacrificial layer Ti/layer preferably ITO, MoO₃, WO₃, V₂O₅, or even AZO, optionally surmounted by a layer (TiN, etc.) of at most 5 nm, better still of at most 3 nm or 2 nm.

The electrode may preferably be directly on the support or else on a layer, for example a light extraction layer, in particular a layer having a higher refractive index than the support, and/or a diffusing layer.

The glass may comprise an outer light extraction element on the face opposite the face with the anode already known per se such as:
addition of a (self-supported) film or deposition of a diffusing layer for volume diffusion,
formation of a microlens system, etc.

The electrode according to the invention may alternatively form a silver bilayer or trilayer (preferably a bilayer), therefore comprising at least two metallic silver layers, and n is equal to 1 and the individual stack comprises SnZnO/SiO₂ or Si₃N₄/ZnO/Ag where Ag is the first silver layer starting from the glass support.

Furthermore, preferably between the first silver layer and the second silver layer, it comprises the following multilayer: sacrificial layer preferably of Ti/layer of ZnO (of the composition described above for b), tq AZO and GZO) preferably having a thickness adjusted for optical properties and for example of at least 50 nm and even between 60 and 110 nm, even of 60 to 100 nm.

However, the sequence described above, SiO₂ or Si₃N₄/a)/d)/b)/c), is preferred between the two silver layers when the wet processing of the OLED is critical because the thick SnZnO layer provides a certain chemical resistance.

Another subject of the present invention is an organic light-emitting diode (OLED) optoelectronic device comprising at least one electrode according to the present invention such as described above. This electrode preferably plays the role of an anode. The OLED then comprises:
an anode formed by the electrode of the present invention,
a layer containing a light-emitting organic substance, and
a cathode.

Preferably, the OLED device may comprise a thicker or thinner OLED system, for example of between 50 and 350 nm.

The electrode is suitable for tandem OLEDs for example described in the publication entitled “Stacked white organic light-emitting devices based on a combination of fluorescent and phosphorescent emitters” by H. Kanno et al., Applied Phys. Lett. 89, 023503 (2006).

The electrode is suitable for OLED devices comprising a highly doped HTL layer (Hole Transport Layer) as described in U.S. Pat. No. 7,274,141 for which the high work function of the last layer of the overlayer is not very important.

Another subject of the present invention is a process for manufacturing an optoelectronic device according to the invention. This process comprises of course the deposition of successive layers constituting the individual stack or stacks described above.

The deposition of all of these layers preferably takes place by magnetron sputtering.

In this process, a plasma is created under high vacuum in the vicinity of a metal or ceramic target comprising the chemical elements to be deposited. The cationic active species of the plasma are attracted by the target (cathode) and collide with the latter. They then pass on their momentum, thus giving rise to the sputtering of the atoms of the target in the form of neutral particles which condense on the substrate forming the desired thin layers.

This process is referred to as “reactive” when the thin layer formed consists of a material resulting from a chemical reaction between the elements extracted from the target, for example the atoms of a metal target, and the gas contained in the plasma, for example oxygen or nitrogen. It is referred to as “non-reactive” when the target has essentially the same chemical composition as the layer formed, for example when it is a ceramic target containing the metal in oxide or nitride form. When the deposition takes place by magnetron sputtering from a ceramic target, the latter is generally doped with at least one metal, for example aluminum, intended to give a sufficient conductivity to the target.

The process according to the invention also comprises a step of heating the transparent electrode at a temperature above 180° C., preferably above 200° C., in particular between 250° C. and 450° C., and ideally between 300 and 350° C., for a duration preferably between 5 minutes and 120 minutes, in particular between 15 and 90 minutes.

It is in the course of this heating (annealing) step that the electrodes of the present invention are distinguished by the absence of the formation of dendrites in the silver layer and by a remarkable improvement in the electrical and optical properties, as will be shown below with the aid of the application example.

### EXAMPLES

In a first deposition series, prepared by magnetron sputtering are, on the one hand, a transparent electrode according to the prior art comprising two individual stacks of thin silver layers on a glass support (comparative E1), and, on the other hand, a transparent electrode according to the invention (E2) which differs from the comparative electrode E1 by the fact that it comprises three thin layers of silicon nitride having a thickness of 4 nm, separating each of the two silver layers from the SnZnO layers.

The conditions for the magnetron sputtering depositions of the layers for comparative E1 and for E2 are the following:
the Si₃N₄:Al layer is deposited by reactive sputtering using a metal target made of aluminum-doped silicon, in an argon/nitrogen atmosphere,
each SnZnO layer is deposited by reactive sputtering using a metal target of zinc and tin in an argon/oxygen atmosphere,
each AZO layer is deposited by sputtering using a ceramic target of zinc aluminum oxide in an argon/oxygen atmosphere, with a low ratio of oxygen,
each silver layer is deposited using a silver target, in a pure argon atmosphere,
each Ti (overblocker) layer is deposited using a titanium target, in a pure argon atmosphere,
the ITO overlayer is deposited using a ceramic target of indium oxide and tin oxide in an atmosphere of argon enriched with a small amount of oxygen, in order to make it not very absorbent, the ITO preferably becoming superstoichiometric in oxygen.

The first Ti overblocker layer may be partially oxidized after deposition of AZO on top. The second Ti overblocker layer may be partially oxidized after deposition of ITO on top.

Table A below summarizes the deposition conditions and also the refractive indices:

TABLE A

| | | | | Refractive |
|---|---|---|---|---|
| | | Deposition | | index at |
| Layer | Target used | pressure | Gas | 550 nm |
| Si₃N₄: Al | Si:Al at 92:8% | 2 × 10⁻³ | N₂/(Ar + | 2.04 |
| | by weight | mbar | N₂) at 43% | |
| AZO | Zn oxide = 98% | 2 × 10⁻³ | O₂/(Ar + | 1.94 |
| | by weight | mbar | O₂) at 1.6% | |
| | Al oxide = 2% | | | |
| | by weight | | | |
| SnZnO | Sn:Zn at 64:36% | 3.5 × 10⁻³ | O₂/(Ar + | 2.06 |
| | by weight | mbar | O₂) at 39% | |
| ITO | In oxide = 90% | 2 × 10⁻³ | O₂/(Ar + | 2.03 |
| | by weight | mbar | O₂) at 1% | |
| | Sn oxide = 10% | | | |
| | by weight | | | |
| Ti | Ti | 8 × 10⁻³ | Ar at 100% | |
| | | mbar | | |
| Ag | Ag | 8 × 10⁻³ | Ar at 100% | |
| | | mbar | | |

Alternatively, it is possible to choose a metal target of zinc and tin doped with antimony comprising, by weight, for example 65% of Sn, 34% of Zn and 1% of Sb, or comprising, by weight, 50% of Sn, 49% of Zn and 1% of Sb.

Table 1 below shows, in comparison, the chemical composition and the thickness of all of the layers forming these two electrodes.

TABLE 1
Chemical composition and thickness of the layers

| | E1 comparative | | E2 according to the invention | |
|---|---|---|---|---|
| | ITO | 50 nm | ITO | 50 nm |
| Second stack | Ti | 1 nm | Ti | 1 nm |
| | Ag | 8 nm | Ag | 8 nm |
| | AZO | 5 nm | AZO | 5 nm |
| | — | — | Si₃N₄ | 4 nm |
| | SnZnO | 75 nm | SnZnO | 67 nm |
| | — | — | Si₃N₄ | 4 nm |
| | AZO | 5 nm | AZO | 5 nm |
| First stack | Ti | 1 nm | Ti | 1 nm |
| | Ag | 8 nm | Ag | 8 nm |
| | AZO | 5 nm | AZO | 5 nm |
| | — | — | Si₃N₄ | 4 nm |
| | SnZnO | 45 nm | SnZnO | 41 nm |

| | |
|---|---|
| Glass substrate | Glass substrate |

The electrodes E1 and E2 are heated for 1 hour at a temperature of 300° C. (annealing).

The light transmission (LT) and the absorption (Abs) and the sheet resistance (R□) of each of the electrodes are measured before and after this annealing.

Table 2 below shows the results of these measurements, before and after annealing, for the electrode E2 according to the invention in comparison with the electrode E1 according to the prior art.

TABLE 2
Optical and electrical properties of the electrodes E1 and E2

| Electrode | LT (%) | Abs (%) | R□ (Ω/□) |
|---|---|---|---|
| E1 before annealing | 85 | 7 | 2.8 |
| E1 after annealing | 81 | 11 | 4.9 |
| E2 before annealing | 85 | 8 | 3.1 |
| E2 after annealing | 87 | 6 | 2.5 |

It is observed that the annealing results in a degradation of the properties of the comparative electrode E1, that is to say a reduction in the light transmission and an increase in the absorption and in the sheet resistance, whereas the electrode E2 according to the invention sees the same properties improved (increase in LT and reduction in Abs and R□).

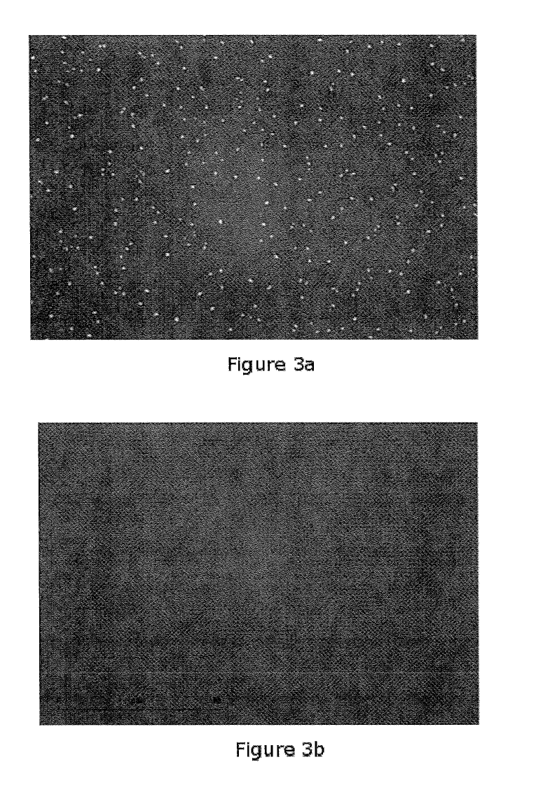

FIGS. 3a and 3b present the optical microscopy images respectively of the electrode E1 (according to the prior art) and of the electrode E2 (according to the invention) after annealing at 300° C. Whereas on the first image (E1) very many white points corresponding to dendrites are observed, these points are completely absent from the second image of the electrode according to the invention (E2).

The use of thin layers of Si₃N₄ as protective layers between an Ag layer and an SnZnO layer therefore makes it possible to completely prevent the formation of dendrites.

In a second deposition series, prepared by magnetron sputtering are, on the one hand, a transparent electrode according to the prior art comprising two individual stacks of thin silver layers on a glass support (comparative E1′) and, on the other hand, a transparent electrode according to the invention (E2′) which differs from the comparative electrode E1′ by the fact that it comprises three thin layers of silica having a thickness of 5 nm, separating each of the two silver layers from the SnZnO layers.

Table 1′ below shows, in comparison, the chemical composition and the thickness of all of the layers forming these two electrodes.

TABLE 1′
Chemical composition and thickness of the layers

| | E1′ comparative | | E2′ according to the invention | |
|---|---|---|---|---|
| | ITO | 50 nm | ITO | 50 nm |
| Second stack | Ti | 1 nm | Ti | 1 nm |
| | Ag | 7 nm | Ag | 7 nm |
| | AZO | 5 nm | AZO | 5 nm |
| | — | — | SiO₂ | 5 nm |
| | SnZnO | 70 nm | SnZnO | 60 nm |
| | — | — | SiO₂ | 5 nm |
| | AZO | 5 nm | AZO | 5 nm |
| First stack | Ti | 1 nm | Ti | 1 nm |
| | Ag | 7 nm | Ag | 7 nm |
| | AZO | 5 nm | AZO | 5 nm |
| | — | — | SiO₂ | 5 nm |
| | SnZnO | 45 nm | SnZnO | 40 nm |

| | |
|---|---|
| Glass substrate | Glass substrate |

The electrodes E1′ and E2′ are heated for 1 hour at a temperature of 300° C. (annealing).

The light transmission (LT) and the absorption (Abs) and the sheet resistance (R□) of each of the electrodes are measured before and after this annealing.

Table 2′ below shows the results of these measurements, before and after annealing, for the electrode E2′ according to the invention in comparison with the electrode E1′ according to the prior art.

TABLE 2′
Optical and electrical properties of the electrodes E1′ and E2′

| Electrode | LT (%) | Abs (%) | R□ (Ω/□) |
|---|---|---|---|
| E1′ before annealing | 84 | 8 | 3.3 |
| E1′ after annealing | 80 | 11 | 5.2 |
| E2′ before annealing | 84 | 8 | 3.4 |
| E2′ after annealing | 85 | 7 | 3.1 |

It is observed that the annealing results in a degradation of the properties of the comparative electrode E1′, that is to say a reduction in the light transmission and an increase in the absorption and in the sheet resistance, whereas the electrode E2′ according to the invention sees the same properties improved (increase in LT and reduction in Abs and R□).

Whereas very many white points corresponding to dendrites are observed on the electrode E1′, these points are completely absent from the electrode according to the invention (E2′).

The use of thin layers of silica as protective layers between an Ag layer and an SnZnO layer therefore makes it possible to completely prevent the formation of dendrites.

The SnZnO layer between the two silver layers has useful properties with regard to the resistance of the electrode to chemical treatments for the OLED, namely cleaning especially using the following procedure:
washing with a detergent with a pH between 6 and 7 at 50° C. under US (at 35 kHz) for 10 minutes,
rinsing with H₂O at 50° C. without US for 10 minutes, and
rinsing with H₂O at 50° C. under US (at 130 kHz) for 10 minutes.

The detergent is “TFDO W” sold by Franklab SA. It is an organic antifoaming detergent containing ionic and nonionic surfactants, chelating agents and stabilizers. Its pH is about 6.8 at 3% dilution.

On inspection of the surface of the electrode E2 thus treated with an optical microscope at a ×10 magnification, no pitting or surface defects were seen.

The aluminum-doped silicon nitride barrier layer may also be replaced by a silicon zirconium nitride layer SiZrN:Al for example produced under a reactive atmosphere from a metallic target having the following constituents given in percent of total weight: Si 76 wt %, Zr 17 wt % and Al 7 wt %.

The following alternative stacks have also yielded satisfactory results (post-anneal).
SnZnO/Si₃N₄:Al/AZO/Ag/AZO/Si₃N₄:Al/SnZnO/Si₃N₄:Al/AZO/Ag/sacrificial Ti layer/ITO
SnZnO/Si₃N₄:Al/Ag/AZO/Si₃N₄:Al/SnZnO/Si₃N₄:Al/AZO/Ag/sacrificial Ti layer/ITO
SnZnO/Si₃N₄:Al/AZO/Ag/Si₃N₄:Al/SnZnO/Si₃N₄:Al/AZO/Ag/sacrificial Ti layer/ITO

The AZO of the first layer and/or the second layer and/or the layer on the first silver layer may be replaced (preferably in all these layers) by GZO for example produced from a ceramic target for example with 98 wt % zinc oxide and 2 wt % Ga oxide.

Therefore, the AZO layers were replaced by GZO layers to create the following stacks:
SnZnO/Si₃N₄:Al/GZO/Ag/Si₃N₄:Al/SnZnO/Si₃N₄:Al/GZO/Ag/sacrificial Ti layer/ITO
Si₃N₄:Al/GZO/Ag/Si₃N₄:Al/SnZnO/Si₃N₄:Al/GZO/Ag/sacrificial Ti layer/ITO.

An electrode was produced by replacing in E2 the first SnZnO underlayer with a layer of titanium oxide (the thickness of which could also be decreased due to its higher optical index). The TiO₂ layer was deposited by sputtering using a ceramic target made of titanium oxide in an argon atmosphere with oxygen. The deposition conditions are given in table B below:

TABLE B

| | | | | Refractive |
|---|---|---|---|---|
| | Target | Deposition | | index at |
| Layer | employed | pressure | Gas | 550 nm |
| TiO₂ | Ti oxide | 2 × 10⁻³ | O₂/(Ar + | 2.44 |
| | | mbar | O₂) at 6% | |

1. A transparent electrode for an organic light-emitting diode, comprising, on a transparent support made of mineral glass, n individual stacks of thin layers, each individual stack successively comprising, starting from the glass support,
a layer of mixed tin zinc oxide, a crystalline layer of zinc oxide, optionally doped,
a metallic silver layer, in contact with the zinc oxide layer, and positioned between each silver layer and the mixed tin zinc oxide layer or layers closest thereto, a layer made of silicon nitride or made of silica.

2. The electrode as claimed in claim 1, wherein n is an integer between 1 and 4.

3. The electrode as claimed in claim 1, wherein a thickness of each of the silicon nitride or silica layer is between 1 and 10 nm.

4. The electrode as claimed in claim 1, wherein at least one individual stack additionally comprises, on top of the metallic silver layer, a sacrificial layer comprising a metal chosen from titanium, nickel, chromium, niobium or a mixture thereof.

5. The electrode as claimed in claim 1, comprising at least two metallic silver layers, and, arranged only on top of the last metallic silver layer, a sacrificial layer comprising a metal chosen from titanium, nickel, chromium, niobium or a mixture thereof.

6. The electrode as claimed in claim 1, comprising a layer of a transparent conductive oxide positioned on top of the last silver layer.

7. The electrode as claimed in claim 1, wherein each of the silicon nitride or silica layer is in contact on one side with a layer of zinc oxide and on the other side with a layer of mixed tin zinc oxide.

8. The electrode as claimed in claim 1, wherein, when n is at least equal to 2, the electrode comprises, between the last layer of one stack and the first layer of the next stack, successively:
a layer of zinc oxide, and
a layer of silicon nitride or silica.

9. The electrode as claimed in claim 1, comprising at least two metallic silver layers, wherein n is equal to 1 and the individual stack that comprises silica or silicon nitride/mixed tin zinc oxide/silica or silicon nitride/zinc oxide/silver is located on top of a silver layer.

10. The electrode as claimed in claim 1, comprising at least two metallic silver layers, wherein n is equal to 1 and the individual stack comprises mixed tin zinc oxide/silica or silicon nitride/zinc oxide/silver where silver is the first silver layer starting from the glass support.

11. The electrode as claimed in claim 1, wherein the layer positioned between each silver layer and each of the mixed tin zinc oxide layers closest to said silver layer is a layer of silica or the layer positioned between each silver layer and each of the mixed tin zinc oxide layers closest to said silver layer is a layer of silicon nitride.

12. An organic light-emitting diode optoelectronic device comprising at least one electrode as claimed in claim 1.

13. A device as claimed in claim 12, wherein the electrode is the anode of the organic light-emitting diode.

14. The device as claimed in claim 12, comprising:
an anode formed by the at least one electrode,
a layer containing a light-emitting organic substance, and
a cathode.

15. A process for manufacturing an optoelectronic device as claimed in claim 13, comprising heating the electrode to a temperature above 180° C. for a duration preferably between 5 minutes and 120 minutes.

16. The electrode as claimed in claim 1, wherein the crystalline layer of zinc oxide is optionally doped with aluminum and/or gallium.

17. The electrode as claimed in claim 9, wherein under a first silver layer starting from the glass support is arranged a multilayer chosen from the following mixed tin zinc oxide/silica, silicon nitride/zinc oxide, niobium oxide (Nb₂O₅) or titanium oxide/silica.

18. The electrode as claimed in claim 10, wherein between the first silver layer and the second silver layer the electrode comprises the following multilayer: sacrificial layer of titanium/layer of zinc oxide.
